(19) United States
(12) Patent Application Publication
(10) Pub. No.: US 2008/0158781 A1
(43) Pub. Date: Jul. 3, 2008

(54) SOLID ELECTROLYTIC CAPACITOR AND LEAD FRAME THEREOF

(75) Inventors: Bang-Hao Wu, Kaohsiung City (TW); Cheng-Liang Cheng, Hsinchu City (TW); Li-Duan Tsai, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/768,914

(22) Filed: Jun. 27, 2007

(30) Foreign Application Priority Data
Dec. 29, 2006 (TW) 95149980

(51) Int. Cl. H01G 9/15; H05K 7/18

(52) U.S. Cl. 361/523; 361/813

(57) ABSTRACT

A solid electrolytic capacitor having multiple capacitor elements and a lead frame is provided. Each capacitor element includes an anode part, a cathode part, and at least one slit or hole, wherein the cathode part is disposed opposite to the anode part and the slit is disposed in the capacitor element. The lead frame has an upper surface and a lower surface where the capacitor elements are stacked on respectively for clipping the lead frame. The lead frame includes an anode terminal part, a cathode terminal part, a first projecting part, and a second projecting part. Wherein, the first and the second projecting parts are disposed at the cathode terminal part, and project towards the upper surface or the lower surface respectively. Especially, the first and second projecting parts are embedded into corresponding slits or holes so as to directly electrically connect the capacitor elements by the lead frame.

### CROSS-REFERENCE TO RELATED APPLICATION

This application claims the priority benefit of Taiwan application serial no. 95149980, filed on Dec. 29, 2006. All disclosure of the Taiwan application is incorporated herein by reference.

### BACKGROUND OF THE INVENTION

1. Field of the Invention

The present invention relates to a solid electrolytic capacitor (SEC). More particularly, the present invention relates to a solid electrolytic capacitor with a low equivalent series resistance (ESR), and a lead frame used in the solid electrolytic capacitor to reduce the equivalent series resistance of the solid electrolytic capacitor.

2. Description of Related Art

A solid electrolytic capacitor has advantages of small size, large capacitance, and superior frequency characteristic, and can be used in decoupling of a power circuit of a central processor unit (CPU). Generally speaking, a plurality of capacitor elements can be stacked to form a high-capacity solid electrolytic capacitor.

FIG. 1A is a schematic cross-sectional view of a conventional solid electrolytic capacitor. Referring to FIG. 1A, the solid electrolytic capacitor 100 includes a plurality of capacitor elements 110, a lead frame 120, and a molding compound 130. Each capacitor element 110 includes an anode part 112, a cathode part 114, and an insulating part 116. More particularly, the cathode parts 114 of the capacitor elements 110 are stacked one another, and a conductive layer 140 is disposed between adjacent capacitor elements 110, such that the plurality of capacitor elements 110 is electrically connected one another.

Referring to FIG. 1A, the lead frame 120 includes an anode terminal part 122 and a cathode terminal part 124. The anode parts 112 of the capacitor elements 110 are electrically connected to the anode terminal part 122, and the cathode parts 114 of the capacitor elements 110 are electrically connected to the cathode terminal part 124. The molding compound 130 encapsulates the capacitor elements 110 and a part of the lead frame 120, so as to protect the solid electrolytic capacitor 100.

However, the conventional solid electrolytic capacitor 100 has the following problems. That is, the equivalent series resistance (ESR) or the equivalent series inductance (ESL) of the solid electrolytic capacitor 100 is high.

FIG. 1B is a schematic view of an equivalent circuit of the solid electrolytic capacitor in FIG. 1A. Referring to FIGS. 1A and 1B, since the capacitor elements 110 are electrically connected one another by the conductive layers 140, a current is transmitted between the capacitor elements 110 through the conductive layers 140. However, the conductive layers 140 have a certain resistance R140. The longer pathway of each capacitor element 110 to reach the lead frame 120 induces higher contact resistance.

In other words, the equivalent series resistance (ESR) of the conventional solid electrolytic capacitor 100 cannot be reduced below a predetermined desired value. Furthermore, with the development of the CPU having a high operating frequency, it is obvious that the conventional solid electrolytic capacitor 100 cannot meet the requirements.

### SUMMARY OF THE INVENTION

In view of the above, the present invention provides a solid electrolytic capacitor with a low equivalent series resistance (ESR) or equivalent series inductance (ESL).

The present invention provides a lead frame for easily carrying a plurality of capacitor elements to fabricate a solid electrolytic capacitor and further reduce the equivalent series resistance (ESR) or equivalent series inductance (ESL) of the solid electrolytic capacitor.

Based on the above, the present invention provides a solid electrolytic capacitor, which includes a plurality of capacitor elements and a lead frame. Each capacitor element includes an anode part, a cathode part, and at least one slit or hole. The cathode part is disposed opposite to the anode part and the slit or hole is disposed in the capacitor elements. The lead frame has an upper surface and a lower surface. The capacitor elements are stacked on the upper surface and the lower surface of the lead frame respectively, so as to clip the lead frame. The lead frame includes an anode terminal part, a cathode terminal part, a first projecting part, and a second projecting part. The anode terminal part is electrically connected to the anode part. The cathode terminal part is electrically connected to the cathode part. The first projecting part is disposed at the cathode terminal part and projects towards the upper surface. The second projecting part is disposed at the cathode terminal part and projects towards the lower surface. The first projecting part and the second projecting part are embedded into corresponding slits or holes, so as to directly electrically connect the capacitor elements by the lead frame.

Based on the above, the present invention further provides a solid electrolytic capacitor, which includes a plurality of capacitor elements and a lead frame. Each capacitor element includes an anode part, a cathode part, and at least one slit or hole. The cathode part is disposed opposite to the anode part and the slit is disposed in the capacitor elements. The lead frame has an upper surface and a lower surface. The capacitor elements are stacked on the upper surface and the lower surface of the lead frame respectively, so as to clip the lead frame. The lead frame includes an anode terminal part, a cathode terminal part, a plurality of first projecting parts, and a plurality of second projecting parts. The anode terminal part is electrically connected to the anode part. The cathode terminal part is electrically connected to the cathode part. The plurality of first projecting parts is disposed at the cathode terminal part and projects towards the upper surface. The plurality of second projecting parts is disposed at the cathode terminal part and projects towards the lower surface. The first projecting parts and the second projecting parts are embedded into corresponding slits or holes respectively, so as to directly electrically connect the capacitor elements by the lead frame.

Based on the above, the present invention also provides a lead frame for carrying a plurality of capacitor elements. Each capacitor element includes an anode part, a cathode part disposed opposite to the anode part, and at least one slit or hole disposed in each capacitor element. The lead frame has an upper surface and a lower surface. The capacitor elements are stacked on the upper surface and the lower surface of the lead frame respectively, so as to clip the lead frame. The lead frame includes an anode terminal part, a cathode terminal part, a first projecting part, and a second projecting part. The anode terminal part is electrically connected to the anode part. The cathode terminal part is electrically connected to the cathode part. The first projecting part is disposed at the cathode terminal part and projects towards the upper surface. The second projecting part is disposed at the cathode terminal part and projects towards the lower surface. The first projecting part and the second projecting part are embedded into corresponding slits or holes respectively, so as to directly electrically connect the capacitor elements by the lead frame.

Based on the above, the present invention further provides the lead frame for carrying a plurality of capacitor elements. Each capacitor element includes an anode part, a cathode part disposed opposite to the anode part, and at least one slit or hole disposed in each capacitor element. The lead frame has an upper surface and a lower surface. The capacitor elements are stacked on the upper surface and the lower surface of the lead frame respectively, so as to clip the lead frame. The lead frame includes an anode terminal part, a cathode terminal part, a plurality of first projecting parts, and a plurality of second projecting parts. The anode terminal part is electrically connected to the anode part. The cathode terminal part is electrically connected to the cathode part. The plurality of first projecting parts is disposed at the cathode terminal part and projects towards the upper surface. The plurality of second projecting parts is disposed at the cathode terminal part and projects towards the lower surface. The first projecting parts and the second projecting parts are embedded into corresponding slits or holes, respectively, so as to directly electrically connect the capacitor elements by the lead frame.

The capacitor elements can be stacked on the upper surface and the lower surface of the lead frame provided by the present invention. Therefore, the capacitor elements can be stacked conveniently and the quantity of the capacitor elements stacked can be adjusted easily, so as to control the capacitance. Furthermore, the cathode terminal part of the lead frame has projecting parts. The projecting parts are embedded into the slit of each of the capacitor elements, such that the current can be transmitted between the capacitor elements directly through the projecting parts. Therefore, the solid electrolytic capacitor provided by the present invention has a low equivalent series resistance (ESR).

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional solid electrolytic capacitor.

FIG. 1B is a schematic view of an equivalent circuit of the solid electrolytic capacitor in FIG. 1A.

FIG. 2 is a schematic cross-sectional view of a solid electrolytic capacitor according to an embodiment of the present invention.

FIGS. 3A and 3B are schematic top views of capacitor elements according to an embodiment of the present invention.

FIG. 3C is a schematic cross-sectional view taken along Line A-A′ in FIG. 3A.

FIG. 4 is a schematic view of an equivalent circuit of the solid electrolytic capacitor in FIG. 2.

FIG. 5 is a schematic perspective view of a lead frame according to an embodiment of the present invention.

FIG. 6A is a schematic side view of a solid electrolytic capacitor using a lead frame without projecting parts.

FIG. 6B is a schematic side view of a solid electrolytic capacitor using a lead frame with projecting parts provided by the present invention.

FIG. 6C is a schematic top view of capacitor elements according to an embodiment of the present invention.

FIG. 7 is a schematic perspective view of another lead frame according to an embodiment of the present invention.

FIG. 8 is a schematic cross-sectional view of a solid electrolytic capacitor with the lead frame of FIG. 7.

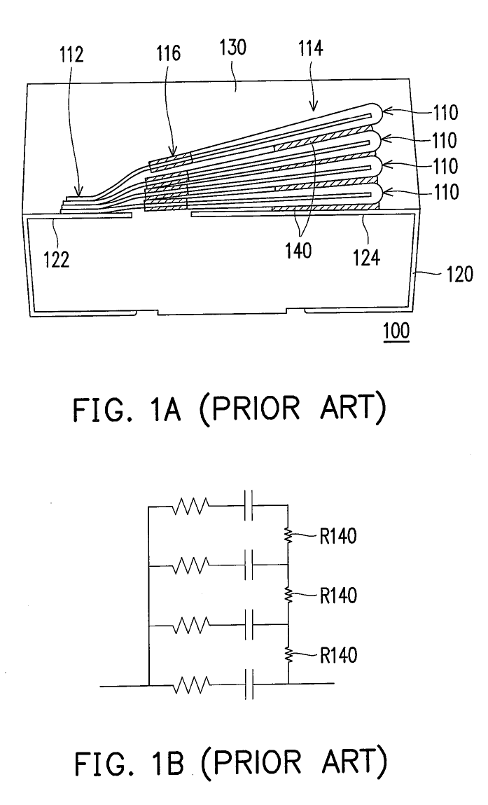

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### The First Embodiment

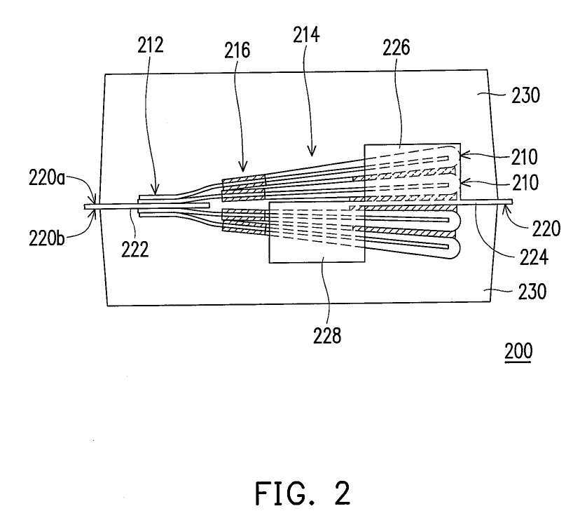

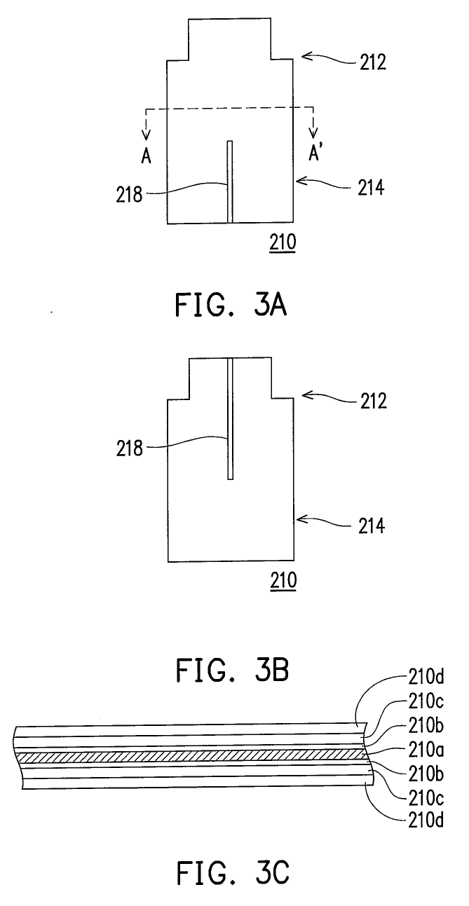

FIG. 2 is a schematic cross-sectional view of a solid electrolytic capacitor according to an embodiment of the present invention. Referring to FIG. 2, the solid electrolytic capacitor 200 includes a plurality of capacitor elements 210 and a lead frame 220. Each capacitor element 210 includes an anode part 212, a cathode part 214, and at least one slit 218 (as shown in FIGS. 3A and 3B). The cathode part 214 is disposed opposite to the anode part 212, and the slit 218 is disposed in the capacitor elements 210. The lead frame 220 has an upper surface 220a and a lower surface 220b, and the capacitor elements 210 are stacked on the upper surface 220a and the lower surface 220b of the lead frame 220 respectively, so as to clip the lead frame 220. The lead frame 220 includes an anode terminal part 222, a cathode terminal part 224, a first projecting part 226, and a second projecting part 228. The anode terminal part 222 is electrically connected to the anode part 212. The cathode terminal part 224 is electrically connected to the cathode part 214. The first projecting part 226 is disposed at the cathode terminal part 224 and projects towards the upper surface 220a. The second projecting part 228 is disposed at the cathode terminal part 224 and projects towards the lower surface 220b. The first projecting part 226 and the second projecting part 228 are embedded into corresponding slits 218, so as to directly electrically connect the capacitor elements 210 by the lead frame 220.

FIGS. 3A and 3B are schematic top views of capacitor elements according to an embodiment of the present invention. FIG. 3C is a schematic cross-sectional view taken along Line A-A′ in FIG. 3A. Firstly, referring to FIG. 3A, in an embodiment, the slit 218 is formed at least in the cathode part 214 or the anode part 212 of each of the capacitor elements 210 which are stacked on the upper surface 220a of the lead frame 220, such that the first projecting part 226 is embedded into the slit 218. Furthermore, as shown in FIG. 3B, the slit 218 is formed at least in the cathode part 214 or the anode part 212 of each capacitor element 210 which are stacked on the lower surface 220b of the lead frame 220, such that the second projecting part 228 is embedded into the slit 218. Moreover, the slit 218 can also be a hole or the like, and is not limited to slit.

Furthermore, the slit 218 (or hole) can be disposed in the cathode part 214 or the anode part 212 of each capacitor element 210. More particularly, the slit 218 is disposed in accordance with the capacitor elements 210 stacked on the upper surface 220a or the lower surface 220b of the lead frame 220.

As shown in FIG. 3C, the capacitor elements 210 may include a valve metal layer 210a, a dielectric layer 210b, a solid electrolyte layer 210c, and a conductive layer 210d. The dielectric layer 210b is formed on the valve metal layer 210a. The solid electrolyte layer 210c is formed on the dielectric layer 210b. The conductive layer 210d is formed on the solid electrolyte layer 210c. Specially, the stacked capacitor elements 210 are electrically connected one another by the conductive layer 210d.

The valve metal layer 210a is made of, for example, aluminum, tantalum, titanium, niobium, or an alloy thereof. The dielectric layer 210b is an oxide of the material of the valve metal layer 210a. For example, when the valve metal layer 210a is made of aluminum, the dielectric layer 210b is aluminum oxide. Definitely, the dielectric layer 210b can also use other dielectric materials. The solid electrolyte layer 210c is formed of conductive polymer. The conductive layer 210d is a mixed colloid of silver and carbon, or a double-layer structure of carbon and silver. The materials of the aforementioned layers is merely illustrated as an example, and those of ordinary skill in the art can change the materials of each layer, which are not limited in the present invention. Furthermore, an insulating part 216 is disposed between the anode parts 212 and the cathode parts 214 of the capacitor elements 210, so as to prevent the anode parts 212 and the cathode parts 214 from being contacted one another to cause short circuit. However, it is not necessary to dispose the insulating part 216 in the capacitor elements 210.

Furthermore, referring to FIG. 2, in an embodiment, the solid electrolytic capacitor 200 further includes a molding compound 230 for encapsulating the capacitor elements 210 and a part of the lead frame 220, thereby protecting the entire solid electrolytic capacitor 200.

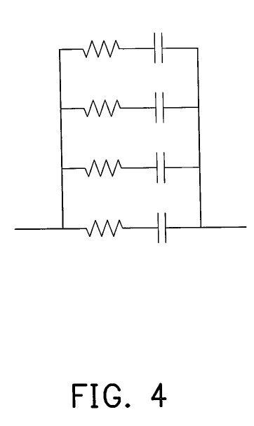

FIG. 4 is a schematic view of an equivalent circuit of the solid electrolytic capacitor in FIG. 2. Referring to FIG. 2, FIGS. 3A-3B, and 4, as the first projecting part 226 and the second projecting part 228 of the lead frame 220 are embedded into the slits 218 of the capacitor elements 210, the stacked capacitor elements 210 can be electrically connected one another through the first projecting part 226 and the second projecting part 228. So, the transmission path of the current is shortened, thereby reducing the equivalent series resistance (ESR) between the capacitor elements 210.

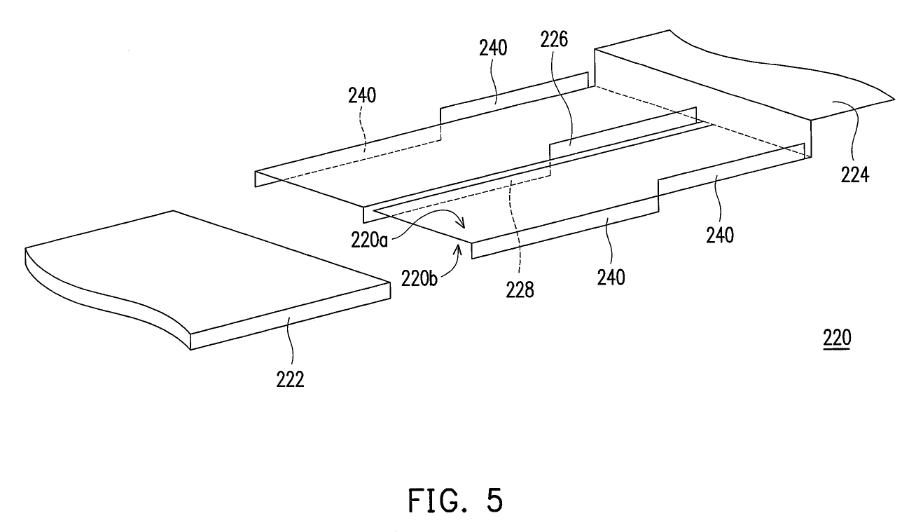

The detailed structure of the lead frame 220 will be described below. FIG. 5 is a schematic perspective view of a lead frame according to an embodiment of the present invention. Referring to FIG. 2, FIGS. 3A-3B, and FIG. 5, the lead frame 220 is suitable for carrying a plurality of capacitor elements 210, and each capacitor element 210 includes an anode part 212, a cathode part 214 disposed opposite to the anode part 212, and at least one slit 218 disposed in each capacitor element 210. The lead frame 220 has an upper surface 220a and a lower surface 220b, and the capacitor elements 210 are stacked on the upper surface 220a and the lower surface 220b of the lead frame 220 respectively, so as to clip the lead frame 220. The lead frame 220 includes an anode terminal part 222, a cathode terminal part 224, a first projecting part 226, and a second projecting part 228. The anode terminal part 222 is electrically connected to the anode part 212. The cathode terminal part 224 is electrically connected to the cathode part 212. The first projecting part 226 is disposed at the cathode terminal part 224 and projects towards the upper surface 220a. The second projecting part 228 is disposed at the cathode terminal part 224 and projects towards the lower surface 220b. The first projecting part 226 and the second projecting part 228 are embedded into the corresponding slits 218, so as to directly electrically connect the capacitor elements 210 by the lead frame 220.

Furthermore, the lead frame 220 can further include a plurality of side plates 240 disposed at both sides of the cathode terminal part 220. The side plates 240 project towards the upper surface 220a or the lower surface 220b, so as to be electrically connected to the side surfaces of the capacitor elements 210 stacked on the upper surface 220a or the lower surface 220b of the lead frame 220. Thereby, the contact area between the lead frame 220 and the capacitor elements 210 is increased, thereby further reducing the equivalent series resistance of the solid electrolytic capacitor 200.

It should be noted that in this embodiment, the first projecting part 226 and the second projecting part 228 are disposed at a central portion of the cathode terminal part 224. Therefore, the path of the current transmitted to the first projecting part 226 and the second projecting part 228 is a shortest path, so as to improve the transmission efficiency of the current between the capacitor elements 210 and reducing the equivalent series resistance (ESR) of the solid electrolytic capacitor 200. The lead frame 220 can be used in various kinds of solid electrolytic capacitors, and are not limited to be used in the aforementioned solid electrolytic capacitor 200.

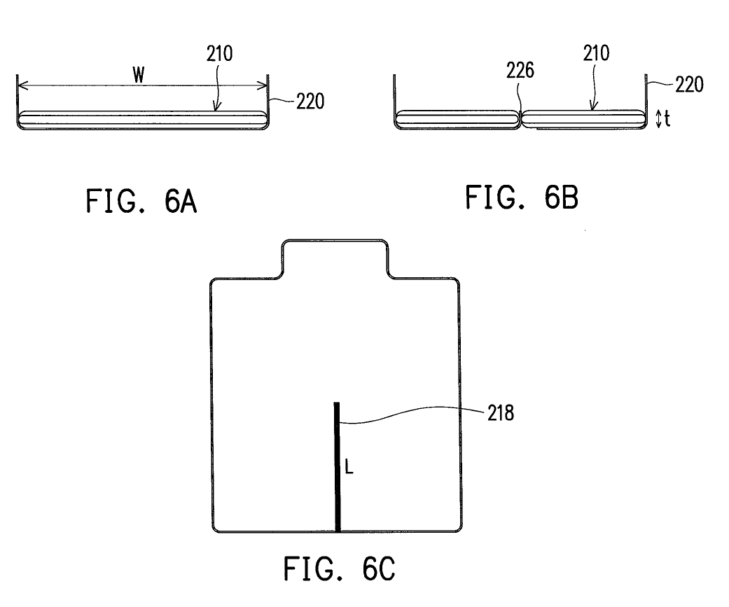

Next, the principle of reducing the equivalent series resistance (ESR) will be illustrated below in detail. FIG. 6A is a schematic side view of a solid electrolytic capacitor using a lead frame without projecting parts. FIG. 6B is a schematic side view of a solid electrolytic capacitor using a lead frame with projecting parts provided by the present invention. FIG. 6C is a schematic top view of capacitor elements according to an embodiment of the present invention. As shown in FIGS. 6A-6C, the capacitor element has a width of w and a thickness of t, and the slit has a length of L.

The transmission path of the current is in direct proportion to the equivalent series resistance (ESR), i.e., the longer the transmission path of the current is, the higher the equivalent series resistance (ESR) is. Therefore, the value of equivalent series resistance (ESR) can be deduced by calculating the transmission path of the current.

Referring to FIG. 6A, the entire lower surface of the capacitor elements 210 contacts the lead frame 220, so the transmission path of the current on the lower surface is considered to be zero. However, the upper surface does not contact the lead frame 220. Therefore, the transmission path of the current on the upper surface can be calculated by the following formula (1):

$${\int }_{0}^{L} {\int }_{0}^{\frac{w}{2}} ( \frac{w}{2} - x ) d x d y = \frac{{w}^{2} L}{8} \qquad ( 1 )$$

Referring to FIG. 6B, when the capacitor elements 210 are stacked on the lead frame 220 with the projecting parts 226, the transmission path of the current on the upper surface of the capacitor elements 210 can be calculated by the following formula (2):

$${\int }_{0}^{L} {\int }_{0}^{\frac{w}{4}} ( \frac{w}{4} - x ) d x d y = \frac{{w}^{2} L}{32} \qquad ( 2 )$$

Furthermore, as shown in FIG. 6B, the transmission path of the current on the lower surface of the capacitor elements 210 can be calculated by the following formula (3):

$${\int }_{0}^{L} {\int }_{0}^{\frac{t}{2}} ( \frac{t}{2} - x ) d x d y = \frac{{t}^{2} L}{8} \qquad ( 3 )$$

Based on the above, the ratio between the transmission paths of the current of the solid electrolytic capacitor in FIGS. 6B and 6A can be calculated by the following formula (4):

$$\frac{final}{Initial} = \frac{\frac{{w}^{2} L}{32} + \frac{{t}^{2} L}{8}}{\frac{{w}^{2} L}{8}} = \frac{1}{2} + \frac{{t}^{2}}{{w}^{2}} = 0.505 \qquad ( 4 )$$

It can be known from the formula (4) that the transmission path of the current of the solid electrolytic capacitor in FIG. 6B is reduced by 50% compared with the transmission path of the current of the solid electrolytic capacitor in FIG. 6A. That is to say, the solid electrolytic capacitor with the projecting parts 226 can greatly reduce the equivalent series resistance (ESR).

### The Second Embodiment

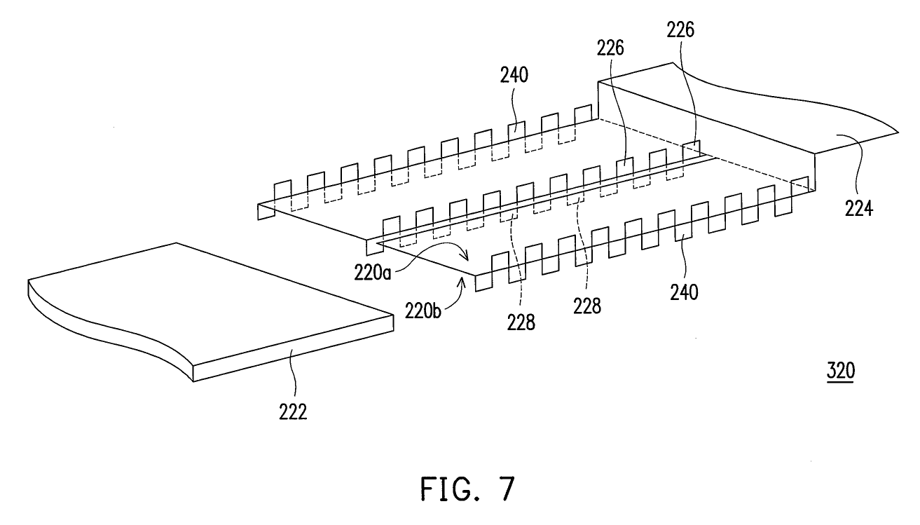

FIG. 7 is a schematic perspective view of another lead frame according to an embodiment of the present invention. Referring to FIG. 2, FIGS. 3A-3B, and FIG. 7, the lead frame 320 is similar to the lead frame 220 in FIG. 5 in the first embodiment, the same components are marked with the same reference numerals, and the details of the same contents will not be repeated.

It should be noted that the designs of the first projecting part 226 and the second projecting part 228 of the lead frame 320 are different from the lead frame 220 as shown in FIG. 5. That is, a plurality of first projecting parts 226 is disposed at the cathode terminal part 224 and projects towards the upper surface 220a. A plurality of second projecting parts 228 is disposed at the cathode terminal part 224 and projects towards the lower surface 220b. The first projecting parts 226 and the second projecting parts 228 are embedded into the corresponding slits 218 respectively, so as to directly electrically connect the capacitor elements 210 by the lead frame 320.

More particularly, the first projecting parts 226 and the second projecting parts 228 are staggered, so as to facilitate the transmission of the current and reduce the equivalent series resistance (ESR) of the solid electrolytic capacitor.

Likewise, the first projecting parts 226 and the second projecting parts 228 are disposed at the central portion of the cathode terminal part 224, so as to facilitate the transmission of the current and reducing the transmission path of the current. The lead frame 320 is suitable for fabricating various kinds of solid electrolytic capacitors. A solid electrolytic capacitor using the lead frame 320 will be illustrated below.

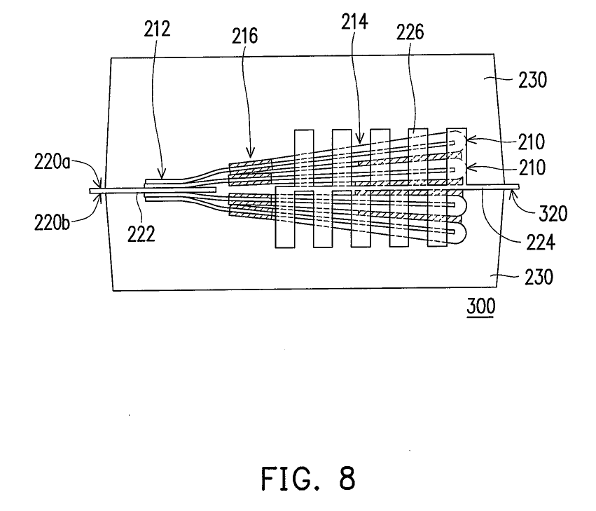

FIG. 8 is a schematic cross-sectional view of a solid electrolytic capacitor with the lead frame in FIG. 7. Referring to FIG. 8, the solid electrolytic capacitor 300 includes a plurality of capacitor elements 210 and a lead frame 320. Each capacitor element 210 includes an anode part 212, a cathode part 214, and at least one slit 218 (or hole) (shown in FIGS. 3A and 3B). The cathode part 214 is disposed opposite to the anode part 212. The slit 218 is disposed in the capacitor elements 210. The lead frame 320 has an upper surface 220a and a lower surface 220b, and the capacitor elements 210 are stacked on the upper surface 220a and the lower surface 220b of the lead frame 320 respectively, so as to clip the lead frame 320. The lead frame 320 includes an anode terminal part 222, a cathode terminal part 224, a plurality of first projecting parts 226, and a plurality of second projecting parts 228. The anode terminal part 222 is electrically connected to the anode part 212. The cathode terminal part 224 is electrically connected to the cathode part 214. The plurality of first projecting parts 226 is disposed at the cathode terminal part 224 and projects towards the upper surface 220a. The plurality of second projecting parts 228 is disposed at the cathode terminal part 224 and projects towards the lower surface 220b. The first projecting parts 226 and the second projecting parts 228 are embedded into the corresponding slits 218 respectively, so as to directly electrically connect the capacitor elements 210 by the lead frame 320.

In the solid electrolytic capacitor 300 using the lead frame 320, the plurality of first projecting parts 226 and the plurality of second projecting parts 228 are staggered and the first projecting parts 226 and the second projecting parts 228 are embedded into the slits 218 of the capacitor elements 210, such that the current can be transmitted between the capacitor elements 210 conveniently. Therefore, the solid electrolytic capacitor 300 has a lower equivalent series resistance (ESR).

Likewise, as shown in FIGS. 3A and 3B, a slit 218 (or hole) is at least formed in the cathode part 214 or the anode part 212 of each capacitor element 210 stacked on the upper surface 220a of the lead frame 320, such that the first projecting part 226 is embedded into the slit 218. Furthermore, a slit 218 is at least formed in the cathode part 214 or the anode part 212 of each capacitor element 210 stacked on the lower surface 220b of the lead frame 320, such that the second projecting part 228 is embedded into the slit 218. Likewise, the slit 218 can also be a hole or the like, and is not limited to slit.

Furthermore, as shown in FIG. 7, the solid electrolytic capacitor 300 further includes a plurality of side plates 240 disposed at both sides of the cathode terminal part 224. The side plates 240 project towards the upper surface 220a or the lower surface 220b, so as to be electrically connected to the side surfaces of the capacitor elements 210 stacked on the upper surface 220a or the lower surface 220b of the lead frame 320. It should be noted that in this embodiment, the side plates 240 projecting towards the upper surface 220a and the side plates 240 projecting towards the lower surface 220b are staggered, so as to facilitate the transmission of the current between the capacitor elements 210 conveniently.

In view of the above, the solid electrolytic capacitor and the lead frame provided by the present invention have the following advantages.

(1) With the design of the lead frame, the capacitor elements can be stacked on the upper surface and the lower surface of the lead frame respectively, so as to clip the lead frame. Therefore, the quantity of the stacked capacitor elements can be adjusted easily, thereby fabricating various solid electrolytic capacitors with different capacitances.

(2) The cathode terminal part of the lead frame has projecting parts. The projecting parts are embedded into the slits of each of the capacitor elements, thereby greatly shortening the transmission path of the current. Therefore, the solid electrolytic capacitor has a low equivalent series resistance (ESR).

(3) In the lead frame, a plurality of first projecting parts projects towards the upper surface and a plurality of second projecting parts projects towards the lower surface. The first projecting parts and the second projecting parts are staggered, so as to facilitate the transmission of the current between the capacitor elements conveniently and greatly reduce the equivalent series resistance (ESR) of the solid electrolytic capacitor.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solid electrolytic capacitor, comprising:
a plurality of capacitor elements, each capacitor element comprising:
an anode part;
a cathode part, disposed opposite to the anode part;
at least one slit or hole, disposed in the capacitor element; and
a lead frame, having an upper surface and a lower surface, wherein the capacitor elements are stacked on the upper surface and the lower surface of the lead frame respectively, so as to clip the lead frame, the lead frame comprising:
an anode terminal part, electrically connected to the anode part;
a cathode terminal part, electrically connected to the cathode part;
a first projecting part, disposed at the cathode terminal part and projecting towards the upper surface;
a second projecting part, disposed at the cathode terminal part and projecting towards the lower surface;
wherein the first projecting part and the second projecting part are embedded into corresponding slits or holes, so as to directly electrically connect the capacitor elements by the lead frame.

2. The solid electrolytic capacitor as claimed in claim 1, wherein the slit or the hole is formed in the cathode part or the anode part of each of the capacitor elements stacked on the upper surface of the lead frame, such that the first projecting part is embedded into the slit or the hole.

3. The solid electrolytic capacitor as claimed in claim 1, wherein the slit or the hole is formed in the cathode part or the anode part of each of the capacitor elements stacked on the lower surface of the lead frame, such that the second projecting part is embedded into the slit or the hole.

4. The solid electrolytic capacitor as claimed in claim 1, wherein the first projecting part and the second projecting part are disposed at a central portion of the cathode terminal part.

5. The solid electrolytic capacitor as claimed in claim 1, further comprising a plurality of side plates disposed at both sides of the cathode terminal part, wherein the side plates project towards the upper surface or the lower surface, so as to be electrically connected to the side surfaces of the capacitor elements stacked on the upper surface or the lower surface of the lead frame.

6. The solid electrolytic capacitor as claimed in claim 1, wherein the capacitor element comprises:
a valve metal layer;
a dielectric layer, formed on the valve metal layer;
a solid electrolyte layer, formed on the dielectric layer; and
a conductive layer, formed on the solid electrolyte layer, wherein the stacked capacitor elements are electrically connected one another by the conductive layer.

7. The solid electrolytic capacitor as claimed in claim 1, further comprising a molding compound encapsulating the capacitor elements and a part of the lead frame.

8. A solid electrolytic capacitor, comprising:
a plurality of capacitor elements, each capacitor element comprising:
an anode part;
a cathode part, disposed opposite to the anode part;
at least one slit or hole, disposed in the capacitor element; and
a lead frame, having an upper surface and a lower surface, wherein the capacitor elements are stacked on the upper surface and the lower surface of the lead frame respectively, so as to clip the lead frame, the lead frame comprising:
an anode terminal part, electrically connected to the anode part;
a cathode terminal part, electrically connected to the cathode part;
a plurality of first projecting parts, disposed at the cathode terminal part and projecting towards the upper surface;
a plurality of second projecting parts, disposed at the cathode terminal part and projecting towards the lower surface;
wherein the first projecting parts and the second projecting parts are embedded into corresponding slits or holes respectively, so as to directly electrically connect the capacitor elements by the lead frame.

9. The solid electrolytic capacitor as claimed in claim 8, the first projecting parts and the second projecting parts are staggered.

10. The solid electrolytic capacitor as claimed in claim 8, wherein the slit or the hole is formed in the cathode part or the anode part of each of the capacitor elements stacked on the upper surface of the lead frame, such that the first projecting parts are embedded into the slit or the hole.

11. The solid electrolytic capacitor as claimed in claim 8, wherein the slit or the hole is formed in the cathode part or the anode part of each of the capacitor elements stacked on the lower surface of the lead frame, such that the second projecting parts are embedded into the slit or the hole.

12. The solid electrolytic capacitor as claimed in claim 8, wherein the first projecting part and the second projecting part are disposed at a central portion of the cathode terminal part.

13. The solid electrolytic capacitor as claimed in claim 8, further comprising a plurality of side plates disposed at both sides of the cathode terminal part, wherein the side plates project towards the upper surface or the lower surface, so as to be electrically connected to the side surfaces of the capacitor elements stacked on the upper surface or the lower surface of the lead frame.

14. The solid electrolytic capacitor as claimed in claim 13, wherein the side plates projecting towards the upper surface and the side plates projecting towards the lower surface are staggered.

15. The solid electrolytic capacitor as claimed in claim 8, wherein the capacitor element comprises:
a valve metal layer;
a dielectric layer, formed on the valve metal layer;
a solid electrolyte layer, formed on the dielectric layer; and
a conductive layer, formed on the solid electrolyte layer, wherein the stacked capacitor elements are electrically connected one another by the conductive layer.

16. The solid electrolytic capacitor as claimed in claim 8, further comprising a molding compound encapsulating the capacitor elements and a part of the lead frame.

17. A lead frame, suitable for carrying a plurality of capacitor elements, wherein each capacitor element comprises an anode part, a cathode part disposed opposite to the anode part, and at least one slit or hole disposed in each capacitor element, the lead frame has an upper surface and a lower surface, and the capacitor elements are stacked on the upper surface and the lower surface of the lead frame respectively, so as to clip the lead frame, the lead frame comprising:
an anode terminal part, electrically connected to the anode part;
a cathode terminal part, electrically connected to the cathode part;
a first projecting part, disposed at the cathode terminal part and projecting towards the upper surface; and
a second projecting part, disposed at the cathode terminal part and projecting towards the lower surface;
wherein the first projecting part and the second projecting part are embedded into the corresponding slit or hole, so as to directly electrically connect the capacitor elements by the lead frame.

18. The lead frame as claimed in claim 17, wherein the first projecting part and the second projecting part are disposed at a central portion of the cathode terminal part.

19. The lead frame as claimed in claim 16, further comprising a plurality of side plates disposed at both sides of the cathode terminal part, wherein the side plates project towards the upper surface or the lower surface, so as to be electrically connected to the side surfaces of the capacitor elements stacked on the upper surface or the lower surface of the lead frame.

20. A lead frame, suitable for carrying a plurality of capacitor elements, wherein each capacitor element comprises an anode part, a cathode part disposed opposite to the anode part, and at least one slit or hole disposed in each capacitor element, the lead frame has an upper surface and a lower surface, and the capacitor elements are stacked on the upper surface and the lower surface of the lead frame respectively, so as to clip the lead frame, the lead frame comprising:
an anode terminal part, electrically connected to the anode part;
a cathode terminal part, electrically connected to the cathode part;
a plurality of first projecting parts, disposed at the cathode terminal part and projecting towards the upper surface; and
a plurality of second projecting parts, disposed at the cathode terminal part and projecting towards the lower surface;
wherein the first projecting parts and the second projecting parts are embedded into corresponding slits or holes respectively, so as to directly electrically connect the capacitor elements by the lead frame.

21. The lead frame as claimed in claim 20, wherein the first projecting parts and the second projecting parts are disposed at a central portion of the cathode terminal part.

22. The lead frame as claimed in claim 20, wherein the first projecting parts and the second projecting parts are staggered.

23. The lead frame as claimed in claim 20, further comprising a plurality of side plates disposed at both sides of the cathode terminal part, wherein the side plates project towards the upper surface or the lower surface, so as to be electrically connected to the side surfaces of the capacitor elements stacked on the upper surface or the lower surface of the lead frame.

24. The lead frame as claimed in claim 23, wherein the side plates projecting towards the upper surface and the side plates projecting towards the lower surface are staggered.
